(19) United States
(12) Patent Application Publication
(10) Pub. No.: US 2025/0246450 A1
(43) Pub. Date: Jul. 31, 2025

(54) METHOD FOR MAXIMIZING THIN-FILMS STRESS THROUGH SEASON IMPROVEMENT

(71) Applicant: Applied Materials, Inc., Santa Clara, CA (US)

(72) Inventors: Aykut AYDIN, Sunnyvale, CA (US); Rui CHENG, Santa Clara, CA (US); Xinhai HAN, Santa Clara, CA (US); Karthik JANAKIRAMAN, San Jose, CA (US)

(21) Appl. No.: 19/039,723

(22) Filed: Jan. 28, 2025

Related U.S. Application Data
(60) Provisional application No. 63/626,150, filed on Jan. 29, 2024.

(51) Int. Cl. H01L 21/67; B08B 7/00; H01J 37/32; H01L 21/3205

(52) U.S. Cl. CPC H01L 21/67017; B08B 7/0035; H01J 37/3244; H01J 37/32862; H01L 21/32051; H01J 2237/3321

(57) ABSTRACT

Embodiments of the disclosure provided herein include systems and methods for increasing tensile stress in tungsten layers in a semiconductor device manufacturing scheme. The system includes a processing chamber defining a processing volume, a gas delivery system fluidly coupled to the processing chamber, and a controller having instructions stored thereon for performing a method of processing a plurality of substrates when executed by one or more processors. The method includes cleaning the processing chamber, seasoning the processing chamber with a non-oxygen containing gas, receiving a substrate into the processing volume of the processing chamber fluidly coupled to the gas delivery system, performing a pre-treatment process on the substrate within the processing chamber, and depositing a tungsten-containing layer onto the substrate.

### CROSS-REFERENCE TO RELATED APPLICATION

This application claims the benefit of and priority to U.S. Provisional Application No. 63/626,150, filed Jan. 29, 2024, which is incorporated by reference herein in its entirety.

### BACKGROUND

### Field

Embodiments of the present disclosure generally relate to deposition processes and chambers. More specifically, embodiments described herein provide for methods of producing tungsten-containing thin films.

### Description of the Related Art

Integrated circuits are made possible by processes which produce intricately patterned material layers on substrate surfaces. Producing patterned material on a substrate requires controlled methods for forming and removing material. Material characteristics may affect how the device operates, and may also affect how the materials are removed relative to one another. However, deviations during thin film deposition affect the characteristics of the thin film, such as line edge roughness (LER) and line width roughness (LWR).

The concept of LER involves the departure of a feature edge from an ideal, smooth shape when observed from a top-down perspective. This metric reflects the irregularity of the edge profile and is commonly quantified using the standard deviation of said profile. The causes of LER span several factors, encompassing uneven photoresist thickness, variations in exposure dose, fluctuations in development time, and non-uniformities in the etch process. LER can significantly influence semiconductor device performance. For instance, it may elevate the resistance of metal lines, impeding device speed, and increase metal line capacitance, consequently diminishing power efficiency. Furthermore, LER can disrupt feature alignment, leading to device defects.

Similarly, line width roughness (LWR) is indicative of the width variation along a feature's length, characterized by the root mean square (RMS) of the edge profile. Factors such as uneven photoresist thickness, exposure dose inconsistencies, variations in development time, and non-uniform etch processes contribute to LWR. Just as with LER, LWR's impact on semiconductor devices is consequential, affecting resistance, capacitance, and feature alignment. Film-induced stress can influence both LWR and LER. Elevating film stress leads to reduced LER and LWR due to enhanced uniformity.

Accordingly, there is a need in the art for improved methods of forming thin films on substrates with increased film stress.

### SUMMARY

Embodiments described herein generally directed electronic device manufacturing and, more particularly, to systems and methods for increasing tensile stress in tungsten layers in a semiconductor device manufacturing scheme.

In an embodiment, a substrate processing system is provided. The substrate processing system includes a processing chamber defining a processing volume, a gas delivery system fluidly coupled to the processing chamber, and a controller having instructions stored thereon for performing a method of processing a plurality of substrates when executed by one or more processors. The method includes cleaning the processing chamber, seasoning the processing chamber with a non-oxygen containing gas, receiving a substrate into the processing volume of the processing chamber fluidly coupled to the gas delivery system, performing a pre-treatment process on the substrate within the processing chamber, and depositing a tungsten-containing layer onto the substrate.

In another embodiment, a gas delivery system for processing a substrate is provided. The gas delivery system includes at least one radical generator, and a controller having instructions stored thereon for performing a method of processing a plurality of substrates when executed by one or more processors. The method includes cleaning a processing chamber, seasoning the processing chamber with a non-oxygen containing gas, receiving a substrate into a processing volume of the processing chamber fluidly coupled to the gas delivery system, performing a pre-treatment process on the substrate within the processing chamber, and depositing a tungsten-containing layer onto the substrate.

In yet another embodiment, a method for forming a thin film on a substrate is provided. The method includes cleaning a processing chamber, seasoning the processing chamber with a non-oxygen containing gas, receiving a substrate into a processing volume of the processing chamber fluidly coupled to a gas delivery system, performing a pre-treatment process on the substrate within the processing chamber, and depositing a tungsten-containing layer onto the substrate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1 is a schematic side view of a processing system that may be used to implement the methods set forth herein, according to an embodiment.

FIG. 2 illustrates a method of processing a substrate in a processing system, according to an embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments herein are generally directed electronic device manufacturing and, more particularly, to systems and methods for increasing tensile stress in tungsten layers in a semiconductor device manufacturing scheme.

Deviations in thin film deposition, such as line edge roughness (LER) and line width roughness (LWR) notably impact semiconductor devices, elevating metal line resistance, hindering speed, increasing capacitance, reducing power efficiency, and causing feature misalignment. Film-induced stress impacts both LWR and LER, and amplifying the film stress reduces these effects by improving uniformity within the thin film.

Seasoning the processing chamber prior to film deposition with, e.g., SiO2, reduces contamination of the subsequently deposited film because the season helps cover the chamber surfaces facing the wafer, thus reducing particle and trace contaminations. However, the inventors have found that the SiO2 seasoning results in reduced film stress of the subsequently deposited film, e.g., WC. The present disclosure provides for alternative season films that can achieve film stress increase while maintaining the season benefits for reducing particles and trace metals.

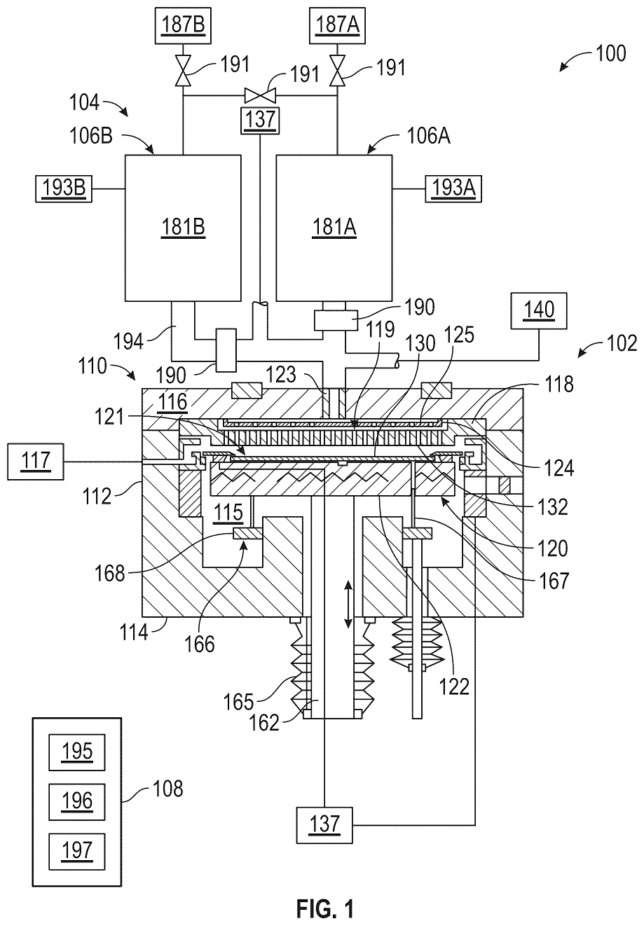

FIG. 1 illustrates a substrate processing system 100. The substrate processing system 100 may be a plasma-enhanced chemical vapor deposition (PECVD) processing chamber. The substrate processing system 100 includes a processing chamber 102, a gas delivery system 104 fluidly coupled to the processing chamber 102, and a system controller 108. The processing chamber 102 includes a chamber lid assembly 110, one or more sidewalls 112, and a chamber base 114, which collectively define a processing volume 115. The processing volume 115 is fluidly coupled to an exhaust 117, such as one or more vacuum pumps, used to maintain the processing volume 115 at sub-atmospheric conditions and to evacuate processing gases and processing by-products therefrom.

The chamber lid assembly 110 includes a lid plate 116 and a showerhead 118 coupled to the lid plate 116 to define a gas distribution volume 119. The showerhead 118 faces a substrate support assembly 120 disposed in the processing volume 115. The substrate support assembly 120 is configured to move a substrate support 122 between a raised substrate processing position (as shown) and a lowered substrate transfer position (not shown). When the substrate support assembly 120 is in the raised substrate processing position, the showerhead 118 and the substrate support 122 define a processing region 121.

The gas delivery system 104 is fluidly coupled to the processing chamber 102 through at least one gas inlet 123 that is disposed through the lid plate 116, one or more sidewalls 112, or both. Processing or cleaning gases delivered by the gas delivery system 104 may flow through the at least one gas inlet 123 and a baffle 124 into the gas distribution volume 119 and are distributed into the processing region 121 through a plurality of openings 132 in the showerhead 118. The chamber lid assembly 110 further includes a perforated diffusion plate 125 disposed between the at least one gas inlet 123 and the showerhead 118. The gases flowed into the gas distribution volume 119 are first diffused by the diffusion plate 125 to provide a more uniform or desired distribution of gas flow into the processing region 121. Processing gases and processing by-products are evacuated from the processing region 121 through exhaust 117 in the one or more sidewalls 112.

A purge gas source 137 in fluid communication with the processing volume 115 is used to flow a chemically inert purge gas, such as argon (Ar), into a region disposed beneath the substrate support 122, e.g., through the opening in the chamber base 114 surrounding a support shaft 162 on which the substrate support 122 is disposed. The purge gas may be used to create a region of positive pressure below the substrate support 122 when compared to the pressure in the processing region 121 during substrate processing. Typically, purge gas introduced through the chamber base 114 flows up and around the edges of the substrate support 122 to be evacuated from the processing volume 115 through openings in the one or more sidewalls 112.

The substrate support assembly 120 includes a movable support shaft 162 that may be surrounded by a bellows 165. The substrate support assembly 120 includes a lift pin assembly 166 comprising a plurality of lift pins 167 coupled to a lift pin hoop 168. The plurality of lift pins 167 are movably disposed in openings formed through the substrate support 122. When the substrate support 122 is disposed in a lowered substrate transfer position (not shown), the plurality of lift pins 167 extend above a substrate receiving surface of the substrate support 122 to lift a substrate 130 and provide access to a backside surface of the substrate 130. When the substrate support 122 is in a raised or processing position, the plurality of lift pins 167 recede beneath the substrate receiving surface of the substrate support 122 to allow the substrate 130 to rest thereon.

Generally, the gas delivery system 104 includes one or more remote plasma sources, a first radical generator 106A and second radical generator 106B, a deposition gas source 140, and a conduit system 194 fluidly coupling the first radical generator 106A and second radical generator 106B and the deposition gas source 140 to the lid assembly 110. The gas delivery system 104 further includes a plurality of isolation valves 190, respectively disposed between the first radical generator 106A and the gas inlet 123 and between the second radical generator 106B and gas inlet 123, which may be used to fluidly isolate each of first radical generator 106A and the second radical generator 106B from the processing chamber 102.

Alternatively, if the first radical generator 106A and the second radical generator 106B are in direct fluid communication (e.g., connected by the conduit system 194), an isolation valve 190 may be used to fluidly isolate the first radical generator 106A and the second radical generator 106B from each other.

Each of the first radical generator 106A and the second radical generator 106B includes a respective first plasma chamber volume 181A and second plasma chamber volume 181B. Each of the first radical generator 106A and the second radical generator 106B is coupled to a respective first power supply 193A and second power supply 193B. The first power supply 193A and second power supply 193B are used to ignite and maintain a plasma of gases delivered to the first plasma chamber volume 181A and second plasma chamber volume 181B from a corresponding first gas source 187A or second gas source 187B. The second radical generator 106B may be used to generate cleaning radicals used in a chamber clean process by igniting and maintaining a cleaning plasma from a halogen-containing gas mixture delivered to the second plasma chamber volume 181B from the second gas source 187B.

The first radical generator 106A may also be fluidly coupled to the second gas source 187B, which delivers a halogen-containing conditioning gas to the first plasma chamber volume 181A to be used in a plasma source condition process. In those embodiments, the gas delivery system 104 may further include a plurality of diverter valves 191, which are operable to direct the halogen-containing gas mixture from the second gas source 187B to the first plasma chamber volume 181A.

Suitable remote plasma sources which may be used for one or both of the first radical generator 106A and the second radical generator 106B include radio frequency (RF) or very high radio frequency (VHRF) capacitively coupled plasma (CCP) sources, inductively coupled plasma (ICP) sources, microwave-induced (MW) plasma sources, electron cyclotron resonance (ECR) chambers, or high-density plasma (HDP) chambers.

As shown, the first radical generator 106A is fluidly coupled to the processing chamber 102 by use of a plurality of conduits 194 which extend upwardly from the gas inlet 123 to connect with an outlet of the first plasma chamber volume 181A. A valve 190 is used to selectively fluidly isolate the first radical generator 106A from the processing chamber 102 and the other portions of the gas delivery system 104. Typically, the valve 190 is closed during the chamber clean process to prevent activated cleaning gases, e.g., halogen radicals, from flowing into the first plasma chamber volume 181A and damaging the surfaces thereof.

The first radical generator 106A and the first valve 190A may be arranged so that a treatment plasma in the first plasma chamber volume 181A is not disposed in a direct line-of-sight with the gas inlet 123. The first plasma chamber volume 181A may be disposed in alignment with the gas inlet 123 to provide a direct line-of-sight from the treatment plasma through the gas inlet 123 and into the processing chamber 102. The direct line-of-sight may beneficially reduce undesired recombination of the treatment radicals by reducing gas-phase collisions therebetween.

The second radical generator 106B is fluidly coupled to the processing chamber 102 via the conduit system 194. The second radical generator 106B may be selectively isolated from the processing chamber 102 and from the other portions of the gas delivery system 104 by use of a second valve 190 that is disposed along the plurality of conduits 194. As shown, the second radical generator 106B is arranged so that a cleaning plasma in the second plasma chamber volume 181B is not disposed in a direct line-of-sight with the valve 190 or the processing chamber 102. Blocking the direct line-of-sight between the cleaning plasma and the valve 190 and the processing chamber 102 prevents halogen ion-induced damage to the components of the valve 190 and the processing chamber 102, thus desirably extending the useful lifetimes thereof.

Operation of the substrate processing system 100 is facilitated by the system controller 108. The system controller 108 includes a programmable central processing unit (CPU) 195, which is operable with a memory 196, which may be a non-volatile memory, and support circuits 197. The CPU 195 is one of any form of general-purpose computer processor used in an industrial setting, such as a programmable logic controller (PLC), for controlling various chamber components and sub-processors. The memory 196, coupled to the CPU 195, facilitates the operation of the processing chamber. The support circuits 197 are conventionally coupled to the CPU 195 and comprise cache, clock circuits, input/output subsystems, power supplies, and the like, and combinations thereof coupled to the various components of the substrate processing system 100 to facilitate control of substrate processing operations therewith.

The instructions in memory 196 are in the form of a program product, such as a program that implements the methods of the present disclosure. In one example, the disclosure may be implemented as a program product stored on computer-readable storage media for use with a computer system. The programs of the program product define functions of the embodiments (including the methods described herein). Thus, the computer-readable storage media, when carrying computer-readable instructions that direct the functions of the methods described herein, are embodiments of the present disclosure.

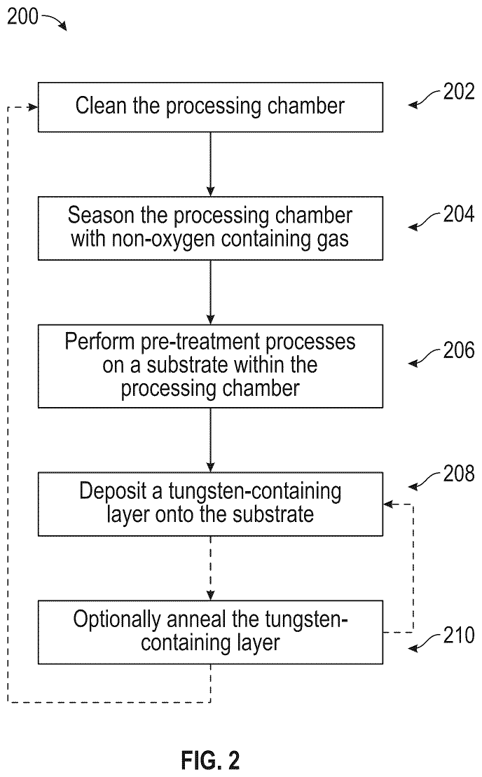

FIG. 2 illustrates a method of conditioning a processing chamber, such as the processing chamber 102 of FIG. 1. In operation 202, the processing chamber 102 is cleaned using a radical-rich cleaning gas, such as NF₃ mixed with a carrier gas such as argon, is flowed into the processing volume using the gas delivery system 104.

The chamber clean process is used to remove undesirable process residue, e.g., accumulated tungsten residue, from the interior surfaces of the processing volume 115. In some embodiments, the chamber clean process is performed after a number of substrates sequentially processed in the processing chamber 102 is greater than or equal to a threshold value, such as greater than or equal to 2 substrates or more, 3 substrates or more, 5 substrates or more, 7 substrates or more, 9 substrates or more, or 11 substrates or more. In some embodiments, the chamber clean process is performed after every substrate 130 processed in the processing chamber 102.

At operation 202 of the method 200, the chamber clean process generally includes activating a cleaning gas in a remote plasma source, and flowing the activated cleaning gas into the processing chamber 102. Typically, the cleaning gas mixture includes a halogen-containing gas and a carrier gas, such as argon or helium. Examples of suitable halogen-containing gases which may be used in the cleaning gas mixture include NF₃, F₂, SF₆, Cl₂, CF₄, C₂F₆, C₄F₈, CHF₃, CF₆, CCl₄, C₂Cl₆, and combinations thereof. In some embodiments, the cleaning gas further comprises a diluent gas, such as Ar, He, or combinations thereof. For example, in one embodiment, the cleaning gas mixture comprises NF₃ and Ar or He. Typically, the activated species of the cleaning gas mixture, e.g., halogen radicals, react with tungsten residue accumulated on surfaces of the processing chamber 102 to form a volatile tungsten species. The volatile tungsten species are evacuated from the processing volume 115 through the exhaust 117.

In some embodiments, a flow rate of the cleaning gas mixture into the remote plasma source, and thus a flow rate of the activated cleaning gas mixture into the processing volume 115, is about 1000 sccm or more, such as about 1500 sccm or more, about 2000 sccm or more, or about 2500 sccm or more. The concentration of halogen-containing gas in the cleaning gas mixture is typically between about 5 vol. % and about 95 vol. %, such as between about 5 vol. % and about 70 vol. %, about 10 vol. % and about 95 vol. %, or more than about 10 vol. %.

In some embodiments, the activated cleaning gas mixture is flowed into the processing volume 115 for a duration of about 5 seconds or more, about 10 seconds or more, about 15 seconds or more.

Here, the chamber clean process is performed using a remote plasma source (e.g., the second radical generator 106B). For example, here, the chamber clean process includes flowing the cleaning gas mixture into the second radical generator 106B, igniting and maintaining a cleaning plasma of the cleaning gas mixture, and flowing the effluent of the cleaning plasma into the processing volume 115. Generally, performing the chamber cleaning operation after each substrate 130 processed in the processing chamber 102 is undesirable due to the lost substrate processing capacity associated therewith. Thus, the chamber cleaning operation is performed after a plurality of substrates 130 have been processed in the chamber so that an average number of substrates processed between chamber cleaning operations is about 2 substrates or more, such as about 5 substrates or more, about 10 substrates or more, about 15 substrates or more, or about 20 substrates or more. In some embodiments, the chamber clean process is performed after every substrate 130 processed in the processing chamber 102.

For example, the second radical generator may be a radical-rich argon (Ar) and nitrogen trifluoride (NF₃) second radical generator 106B, utilizes a blend of Ar and NF₃ gases to initiate plasma generation. This particular type of plasma source demonstrates remarkable efficacy in the removal of organic contaminants, such as photoresist residue and polymer films. The cleaning process unfolds by propelling the Ar+NF₃ plasma through the chamber designated for cleaning at a reduced pressure level. The reactive species within in the plasma react with the contaminants adhering to the chamber walls, thereby creating volatile compounds that are subsequently evacuated from the system. Following this stage, the processing chamber 102 undergoes a rinsing procedure involving the introduction of a pure gas, such as argon or nitrogen, to effectuate the removal of any residual contaminants that may persist.

An example of the chamber cleaning process using the radical-rich Ar+NF₃ second radical generator 106B is may include evacuating the chamber to achieve a state of low pressure. Subsequently, generating the Ar+NF₃ plasma within the second radical generator 106B then transporting the plasma to the target chamber through a vacuum tube. The reactive species present in the plasma and the contaminants adhering to the chamber walls react, resulting in the creation of volatile compounds. These volatile compounds are then exhausted from the system. Finally, the chamber is rinsed with a pure gas, such as argon or nitrogen, for the purpose of eradicating any residual contaminants that may remain.

In operation 204, the processing volume within the processing chamber 102, including the substrate support 122, is exposed to a non-oxygen containing gas. Seasoning a processing chamber 102 with a non-oxygen containing gas entails the deposition of a thin non-oxygen containing gas layer onto the internal surfaces of the processing chamber 102. This varies from the typical seasoning procedure which includes reacting a silicon-containing gas with an oxygen-containing gas within the confines of the processing chamber 102, e.g., to produce silicon oxide (SiO₂). In the present disclosure, a non-oxygen containing gas, such as silicon nitride (Si₃N₄), carbon, amorphous boron, and boron nitride (BN), is flowed into the processing chamber 102 instead. The underlying purpose of this process is twofold: (1) to safeguard the processing chamber 102 surfaces against contamination and (2) to enhance the quality of the films that are deposited or etched therein. The non-oxygen containing gas layer serves as a protective barrier, effectively isolating the processing chamber 102 surfaces from the process gases and reactants. This, in turn, impedes the adhesion of contaminants to the processing chamber 102 surfaces and mitigates their incorporation into the deposited or etched films.

Furthermore, the non-oxygen containing gas layer contributes to the amelioration of film uniformity. This is attributed to the provision of a smooth and consistent surface by the non-oxygen containing gas layer, facilitating the growth of films with uniform properties. Seasoning is a post-cleaning procedure, primarily undertaken subsequent to cleaning the processing chamber 102, as the cleaning process can strip away the pre-existing non-oxygen containing gas layer from the surfaces of the processing chamber 102.

Oxygen containing gases, when used to season processing chambers 100 such as SiO₂, reduce film stress lower than if the processing chamber 102 was not seasoned. Because the season helps cover the processing chamber 102 surfaces facing the substrate 130 and reduce substrate particle counts and trace metal contaminations, alternative season films with low oxygen can achieve the higher stress increases while preventing particle and trace metal contamination.

The advantages of seasoning a processing chamber 102 with a non-oxygen containing gas encompass a reduction in contamination of deposited or etched films, the enhancement of film uniformity, diminished harm to processing chamber 102 surfaces, and an extended processing chamber 102 lifespan while increasing the film stress of the deposited film, such as a tungsten-containing film.

At operation 206, pre-treatment processes are performed within the processing chamber 102. These processes are conducted on the substrate 130 before the desired film deposition, with the objective of preparing the substrate surface. This process involves cleaning the substrate 130, eliminating any contaminants present, and establishing a surface that is conducive to the deposition of the desired film.

Various types of pre-treatments are available for use in chemical vapor deposition (CVD), and the selection of a particular pre-treatment method depends on factors such as the substrate 130 material, the desired film material, and the specific deposition conditions. Pre-treatments may include chemical etching, which involves exposing the substrate 130 to chemical solutions that can either remove contaminants or modify the surface. Ion bombardment, on the other hand, entails bombarding the substrate 130 with ions to either eliminate contaminants or induce surface roughness. Lastly, annealing prior to deposition involves heating the substrate 130 to high temperatures to eliminate contaminants and improve surface properties.

Regarding growth of tungsten on a substrate 130, the pre-treatment may include chemical etching to modify the substrate surface, particularly by eliminating native oxide layers using hydrofluoric acid. Ion bombardment may be employed to roughen the substrate 130 surface, enhancing the number of nucleation sites for tungsten growth. Annealing in a hydrogen atmosphere can improve substrate 130 surface properties by removing contaminants and establishing a clean, atomically flat surface. The pretreatment step may include using a cyclic N₂+H₂+Ar plasma treatment along with a WF₆ soak to clean and prepare the surface of a substrate 130 surface before deposition or etching.

The N₂+H₂+Ar plasma treatment constitutes a dry cleaning procedure employing plasma to eliminate contaminants from the surface of the substrate 130. Plasma generation is accomplished by the application of a high voltage to a mixture of nitrogen (N₂), hydrogen (H₂), and argon (Ar) gases. The energetic species within the plasma interact with the contaminants adorning the surface of the substrate 130, leading to the formation of volatile compounds that are subsequently evacuated from the system.

Conversely, the WF₆ soak constitutes a wet cleaning method that relies on tungsten hexafluoride (WF₆) to cleanse the surface of the substrate 130. WF₆ is dissolved in a solvent, and the substrate 130 is immersed in the solution. During this immersion, WF₆ engages in reactions with the contaminants on the surface of the substrate 130, generating volatile compounds that dissolve within the solvent medium.

Another N₂+H₂+Ar plasma treatment may follow the WF₆ soak to eliminate any residual WF₆ or other lingering contaminants from the surface of the substrate 130. The specific number of cycles involving the WF₆ soak and N₂+H₂+Ar plasma treatment is contingent upon the nature of the substrate 130 and the precise requisites of the deposition or etching process at hand.

This multifaceted pretreatment operation offers several advantages, including the comprehensive removal of an array of contaminants from the surface of the substrate 130, encompassing organic, metal, and particle contaminants. Additionally, it enhances the adhesion and uniformity of the films to be deposited or etched while simultaneously diminishing the likelihood of defects in the resultant films.

At operation 208, a tungsten-containing layer is deposited onto the substrate 130. Deposition may occur through the introduction of C₃H₆ and WF₆ into the processing chamber 102 employing capacitively coupled plasma (CCP) constitutes a method for the deposition of tungsten (W) films onto the substrate 130. This procedure hinges upon the chemical vapor deposition (CVD) of WF₆, facilitated by propane (C₃H₆) as a reducing agent.

The process typically includes generating a CCP within the processing chamber 102, using a blend of C₃H₆ and WF₆ gases. The deposition of the W film onto the substrate 130 occurs through the reaction between WF₆ and the reducing agent, C₃H₆. Upon completion of the deposition, the plasma is deactivated, and the processing chamber 102 undergoes cooling to attain room temperature.

At optional operation 210, the substrate 130 and tungsten-containing film may be annealed. For example, the substrate 130 and tungsten-containing film may undergo gas annealing. This includes subjecting the substrate 130 to heating within a pressurized processing chamber 102 containing gas. The presence of this gas serves a dual purpose: safeguarding the substrate 130 from oxidation and facilitating even heating. Gas annealing serves as a means to enhance the properties of materials, encompassing aspects like crystallinity, electrical conductivity, and mechanical strength.

The specific parameters governing gas annealing, comprising gas composition, pressure, temperature, and duration, are contingent upon the material to be annealed and the intended outcomes. After deposition, a designated gas is introduced into the processing chamber 102, elevating the pressure. The designated gas may be any suitable gas, such as hydrogen (H₂) or nitrogen (N₂). Heating is then applied to elevate the processing chamber 102's temperature to the prescribed annealing level. The substrate 130 remains at the annealing temperature for a predetermined period, such as about 0.5 minutes to about 60 minutes, such as about 1 minute to about 30 minutes. Following this, cooling is initiated to return the processing chamber 102 to room temperature, accompanied by the release of gas from the processing chamber 102. The final step involves the removal of the substrate 130 from the processing chamber 102.

The benefits of gas annealing within a CVD processing chamber 102 encompass protection of the substrate 130 against oxidation, promotion of uniform heating, adaptability for annealing a diverse array of materials, and the facilitation of precise control over the annealing process.

The method 200 may then optionally repeat operation 202-210 until substrate processing is completed.

The present disclosure provides for improved methods of producing thin films on a substrate. Specifically, the present disclosure provides for a method to improve seasoning in the processing chamber that results in increased thin film stress above at least 2.6 GPa.

When introducing elements of the present disclosure or exemplary aspects or embodiments thereof, the articles “a,” “an,” “the” and “said” are intended to mean that there are one or more of the elements.

The terms “comprising,” “including” and “having” are intended to be inclusive and mean that there may be additional elements other than the listed elements.

The term “coupled” is used herein to refer to the direct or indirect coupling between two objects. For example, if object A physically touches object B and object B touches object C, the objects A and C may still be considered coupled to one another—even if objects A and C do not directly physically touch each other. For instance, a first object may be coupled to a second object even though the first object is never directly in physical contact with the second object.

While the foregoing is directed to embodiments of the present disclosure, other and further embodiments of the disclosure may be devised without departing from the basic scope thereof, and the scope thereof is determined by the claims that follow.

What is claimed is:

1. A substrate processing system, comprising:
a processing chamber defining a processing volume;
a gas delivery system fluidly coupled to the processing chamber; and
a controller having instructions stored thereon for performing a method of processing a plurality of substrates when executed by one or more processors, the method comprising:
(a) cleaning the processing chamber;
(b) seasoning the processing chamber with a non-oxygen containing gas;
(c) receiving a substrate into the processing volume of the processing chamber fluidly coupled to the gas delivery system;
(d) performing a pre-treatment process on the substrate within the processing chamber; and
(e) depositing a tungsten-containing layer onto the substrate.

2. The substrate processing system of claim 1, wherein cleaning the processing chamber comprises flowing a plasma generated from radical-rich argon and nitrogen triflouride.

3. The substrate processing system of claim 1, wherein the non-oxygen containing gas is silicon nitride, carbon, amorphous boron, or boron nitride.

4. The substrate processing system of claim 1, wherein the pre-treatment comprises a cyclic N₂+H₂+Ar plasma treatment and a wet soak.

5. The substrate processing system of claim 1, wherein depositing a tungsten-containing layer includes flowing C₃H₆ and WF₆ and using a capacitively-coupled plasma.

6. The substrate processing system of claim 1, the method further comprising:
(f) annealing the tungsten-containing layer.

7. The substrate processing system of claim 6, wherein annealing comprises a gas anneal using hydrogen.

8. A gas delivery system for processing a substrate, comprising:
at least one radical generator; and
a controller having instructions stored thereon for performing a method of processing a plurality of substrates when executed by one or more processors, the method comprising:
(a) cleaning a processing chamber;
(b) seasoning the processing chamber with a non-oxygen containing gas;
(c) receiving a substrate into a processing volume of the processing chamber fluidly coupled to the gas delivery system;
(d) performing a pre-treatment process on the substrate within the processing chamber; and
(e) depositing a tungsten-containing layer onto the substrate.

9. The gas delivery system of claim 8, the method further comprising:
(f) annealing the tungsten-containing layer.

10. The gas delivery system of claim 8, wherein cleaning the processing chamber comprises flowing a plasma generated from radical-rich argon and nitrogen triflouride.

11. The gas delivery system of claim 8, wherein the non-oxygen containing gas is silicon nitride, carbon, amorphous boron, or boron nitride.

12. The gas delivery system of claim 8, wherein the pre-treatment comprises a cyclic N₂+H₂+Ar plasma treatment and a wet soak.

13. The gas delivery system of claim 8, wherein depositing a tungsten-containing layer includes flowing C₃H₆ and WF₆ and using a capacitively-coupled plasma.

14. The gas delivery system of claim 9, wherein annealing comprises a gas anneal using hydrogen.

15. A method for forming a thin film on a substrate, comprising:
(a) cleaning a processing chamber;
(b) seasoning the processing chamber with a non-oxygen containing gas;
(c) receiving a substrate into a processing volume of the processing chamber fluidly coupled to a gas delivery system;
(d) performing a pre-treatment process on the substrate within the processing chamber; and
(e) depositing a tungsten-containing layer onto the substrate.

16. The method of claim 15, wherein cleaning the processing chamber comprises flowing a plasma generated from radical-rich argon and nitrogen triflouride.

17. The method of claim 15, wherein the non-oxygen containing gas is silicon nitride, carbon, amorphous boron, or boron nitride.

18. The method of claim 15, wherein the pre-treatment comprises a cyclic N₂+H₂+Ar plasma treatment and a wet soak.

19. The method of claim 15, further comprising:
(f) annealing the tungsten-containing layer.

20. The method of claim 19, wherein annealing comprises a gas anneal using hydrogen.
